(19) United States
(12) Patent Application Publication
(10) Pub. No.: US 2026/0142680 A1
(43) Pub. Date: May 21, 2026

(54) EVAPORATIVE COOLING OF PORTABLE ELECTRONIC DEVICES

(71) Applicant: QUALCOMM Incorporated, San Diego, CA (US)

(72) Inventors: Palash Vadiraj ACHARYA, San Diego, CA (US); Ajay VADAKKEPATT, San Diego, CA (US); Ashkan MOVAGHAR, San Diego, CA (US); Dohwan KIM, San Diego, CA (US); Ajit Kumar VALLABHANENI, Carlsbad, CA (US)

(21) Appl. No.: 18/950,941

(22) Filed: Nov. 18, 2024

(51) Int. Cl. H04B 1/036; H05K 7/20

(52) U.S. Cl. CPC H04B 1/036; H05K 7/20327

(57) ABSTRACT

A device includes a cover configured to provide an outer surface of a portable electronic device. The device also includes a heat dissipation mechanism integrated in the cover and configured to evaporatively cool the portable electronic device. The heat dissipation mechanism includes a set of liquid retention structures located at the outer surface. The heat dissipation mechanism also includes a set of electrodes coupled to the set of liquid retention structures and configured to enable transport of liquid at the liquid retention structures from a first location of the outer surface to a second location of the outer surface.

### FIELD

Various features relate to a heat dissipation mechanism for evaporative cooling of portable electronic devices.

### DESCRIPTION OF RELATED ART

In state-of-the-art electronic devices, there is generally an expectation that integrated device packages have a small form factor, a low cost, a tight power budget, and high performance. These various goals are often in conflict. As an example, assembling components of an electronic device into a package with a smaller form factor generally impedes heat management, which limits performance of the electronic device.

The heat transfer pathway in electronic devices, such as a mobile device, initiates at the chipset where the workloads are executed, which leads to power being dissipated on various processor cores. This heat is then transferred to the back and front surface of the mobile phone via a network of thermal interface materials, thermal gels, vapor chambers, heat spreaders, aerogels, etc. The heat from the external surface of the mobile device is then picked up by the ambient air and dissipated, via convection and radiation pathways, for heat removal. Therefore, the rate at which heat can be dissipated by the mobile device is highly constrained by the rate at which it can be picked up by the ambient air from the device surface, which is typically quantified by a metric referred to as surface heat transfer coefficient. In an analogy to an electrical circuit, the surface-to-air thermal resistance becomes a bottleneck for the power dissipation capability under thermal constraints and thereby limits the performance of the mobile device.

### SUMMARY

Various features relate to integrated circuit devices.

One example provides a device that includes a cover configured to provide an outer surface of a portable electronic device. The device also includes a heat dissipation mechanism integrated in the cover and configured to evaporatively cool the portable electronic device. The heat dissipation mechanism includes a set of liquid retention structures located at the outer surface. The heat dissipation mechanism also includes a set of electrodes coupled to the set of liquid retention structures and configured to enable transport of liquid at the liquid retention structures from a first location of the outer surface to a second location of the outer surface.

Another example provides a portable electronic device that includes a display panel at a front surface of the portable electronic device and an integrated circuit coupled to the display panel. The portable electronic device includes a cover coupled to the integrated circuit at a back surface of the portable electronic device. The portable electronic device also includes a heat dissipation mechanism integrated in the cover and configured to evaporatively cool the portable electronic device. The heat dissipation mechanism includes a set of liquid retention structures located at the back surface. The heat dissipation mechanism also includes a set of electrodes coupled to the set of liquid retention structures and configured to enable transport of liquid at the liquid retention structures from a first location of the back surface to a second location of the back surface.

Another example provides a method of cooling a portable electronic device and includes detecting a hotspot on a surface of the portable electronic device. The method also includes biasing electrodes at a set of liquid retention structures at the surface of the portable electronic device to transport liquid from a first location of the surface to a second location of the surface that corresponds to the hotspot.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic back view and cross-sectional profile view of an exemplary device that includes a heat dissipation mechanism configured to perform evaporative cooling.

FIG. 2 illustrates a schematic back view and cross-sectional profile view of an exemplary device that includes a heat dissipation mechanism configured to perform evaporative cooling.

FIG. 3 illustrates a schematic back view of an exemplary device that includes a heat dissipation mechanism configured to perform evaporative cooling.

FIG. 4 illustrates a schematic back view of an exemplary device that includes a heat dissipation mechanism configured to perform evaporative cooling.

FIG. 5 illustrates an exemplary flow diagram of a method of cooling a portable electronic device.

FIG. 6 illustrates an exemplary flow diagram of a method of cooling a portable electronic device.

FIG. 7 illustrates various electronic devices that may integrate a heat dissipation mechanism configured to perform evaporative cooling described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines. While advances in electronic devices, such as the use of stacking dies or packaged IC devices has several benefits, heat management can be problematic when such schemes are used.

Devices and methods are disclosed that include a control system-based evaporative cooling technique to enhance dissipation of heat that is generated by operation of electronic devices. “Evaporative cooling” refers to the cooling of a surface via evaporation of a thin film of water from the surface. The disclosed techniques utilize the property that liquids with a large enthalpy of vaporization, such as water, absorb a large amount of heat to evaporate, which results in very high heat transfer coefficients and enhances cooling of the electronic devices.

According to an aspect, the back surface of a mobile device, such as a mobile phone, includes microstructures that can retain water such that a user of the mobile device does not experience any moisture or wetting-based discomfort while using the mobile device. Additionally, or alternatively, the microstructures can be implemented in an external device cover that can be attached to a mobile device. The water used for evaporative cooling can be harnessed from water vapor in the atmosphere, supplied by the user from an external water source, or both. According to an aspect, the microstructures can include hygroscopic (e.g., water absorbing) material that has the capability to absorb moisture from the atmosphere.

However, because the rate of which such hygroscopic materials can absorb atmospheric moisture is limited, overall performance improvement of the mobile device is further enhanced by a control system-based heat dissipation mechanism that can activate evaporative cooling. In particular, because the heat that is generated by operation of the mobile device is typically concentrated in the vicinity of high-performance integrated circuits within the mobile device, the resulting skin temperature on the back surface of the mobile phone is non-uniform, with hotspots corresponding to areas of the back surface having higher skin temperatures, while other areas of the back surface have lower temperatures. The control system-based heat dissipation mechanism can detect such hotspots and direct the water retained in the microstructures to the hotspot locations for more efficient, precise, and targeted surface cooling.

### Exemplary Device Including a Heat Dissipation Mechanism Configured to Perform Evaporative Cooling

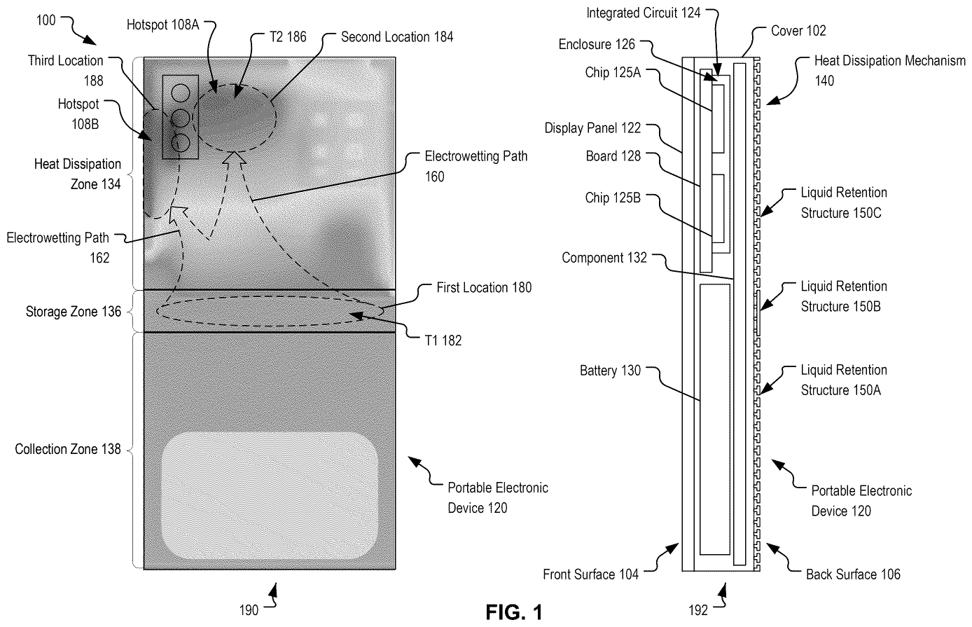

FIG. 1 illustrates a schematic back view 190 of an exemplary device 100, with an overlaid heat map, and a cross-sectional profile view 192 of the exemplary device 100 that includes a heat dissipation mechanism 140 configured to perform evaporative cooling. In the example illustrated in FIG. 1, the device 100 includes, or corresponds to, a cover 102 of a portable electronic device 120, such as a mobile phone or tablet device, as illustrative, non-limiting examples.

The portable electronic device 120 includes a display panel 122 at a front surface 104 of the portable electronic device 120 and an integrated circuit 124 coupled to the display panel 122. The cover 102 is coupled to the integrated circuit 124 at a back surface 106 of the portable electronic device 120. The cover 102 is configured to provide an outer surface (e.g., the back surface 106) of the portable electronic device 120. In some embodiments, the cover 102 is formed of glass, metal, plastic, or the like, and is a component of the portable electronic device 120, while in other embodiments the cover 102 is removably attachable to the portable electronic device 120.

The display panel 122 corresponds to a liquid crystal display (LCD) or other type of display device attached to or embedded in the front surface 104 of the portable electronic device 120. The portable electronic device 120 may also include an electronic assembly that includes a board 128, such as a printed circuit board (PCB) that is coupled to the one or more chips or chiplets of the integrated circuit 124, illustrated as a first chip 125A (e.g., a processor) and a second chip 125B (e.g., a memory) that are within an enclosure 126. In some implementations, the portable electronic device 120 includes a packaged IC device having two or more dies arranged in a stacked three-dimensional (3D) arrangement. In some implementations, the integrated circuit 124 include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the integrated circuit 124. Additionally, or alternatively, one or both of the chips 125A, 125B may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. As one example, the chip 125A can include circuitry defining one or more processor cores, and the chip 125B can include circuitry defining a plurality of memory cells.

The portable electronic device 120 also includes a battery 130 coupled to the integrated circuit 124 and the display panel 122. The portable electronic device 120 further includes one or more additional components, illustrated as a representative component 132, such as one or more of a middle frame, a vapor chamber, a heat sink (e.g., a graphite heat spreader), an antenna carrier, etc.

Conventionally, high-performance devices such as the portable electronic device 120 can include high-power electronics integrated in one or more integrated circuits. For example, the integrated circuit 124 can include one or more central processing units (CPUs), one or more graphics processing units (GPUs), one or more Neural Signal Processors (NSPs), or a combination thereof. During aggressive CPU, GPU, and/or NSP use cases, performance of the portable electronic device 120 may be limited by a skin temperature threshold criterion, such as an upper limit of 45 degrees Celsius (45° C.) (e.g., approximately 113 degrees Fahrenheit (113° F.)) at any location on the outer surface of the portable electronic device 120, as an illustrative, non-limiting example.

In order to cool off a conventional device when a portion of the outer surface of the conventional device exceeds the skin temperature threshold, device operation is typically throttled down, such as by reducing a clock rate or frame rate of the CPU/GPU/NSP, until a sufficient amount of heat has dissipated via convection and/or radiation to reduce the skin temperature to below the threshold. Such throttling reduces the overall performance of the device. Performance of skin-temperature limited mobile electronic devices can be improved with the introduction of an evaporative cooling mechanism that collects atmospheric moisture in liquid retention structures on the back of the mobile electronic device and allows the collected liquid to evaporate when the skin temperature approaches or exceeds the skin temperature threshold. The evaporative cooling mechanism thus extends the length of time the device can operate before having to throttle device operation due to the skin temperature threshold being exceeded.

In an illustrative, non-limiting example, using evaporative cooling can result in a 20% improvement in GPU sustained performance. However, because the temperature is non-uniformly distributed across the surface of the device, overall device performance is limited by the amount of water available for evaporation in the vicinity of a higher-temperature “hotspot” of the surface. To illustrate, the water in the vicinity of a hotspot can evaporate away before water at cooler locations, resulting in the hotspot exceeding the skin temperature threshold and necessitating device throttling, even though water is still available for evaporative cooling at other regions of the surface.

The device 100 addresses these and other concerns by including a control system-based heat dissipation mechanism 140 to direct liquid to specific locations of the back surface 106 to provide directed evaporative cooling to hotspots where the skin temperature exceeds a threshold. Although the liquid is typically described as water that can be harvested from atmospheric moisture in the following examples, in other examples other liquids can be used instead of water or in combination with water (e.g., as a mixture), such as ethanol or methanol as illustrative, non-limiting examples of fluids with relatively high enthalpy of vaporization. As depicted in the exemplary heat map overlay on the back surface 106 illustrated in the back view 190, regions of higher skin temperature of the back surface 106 (shown in darker shading) occur in the upper half of the back surface 106, particularly in the vicinity of the first chip 125A and the second chip 125B, while regions of lower skin temperature (shown as lighter shading) occur in the lower half of the back surface 106 in the vicinity of the battery 130.

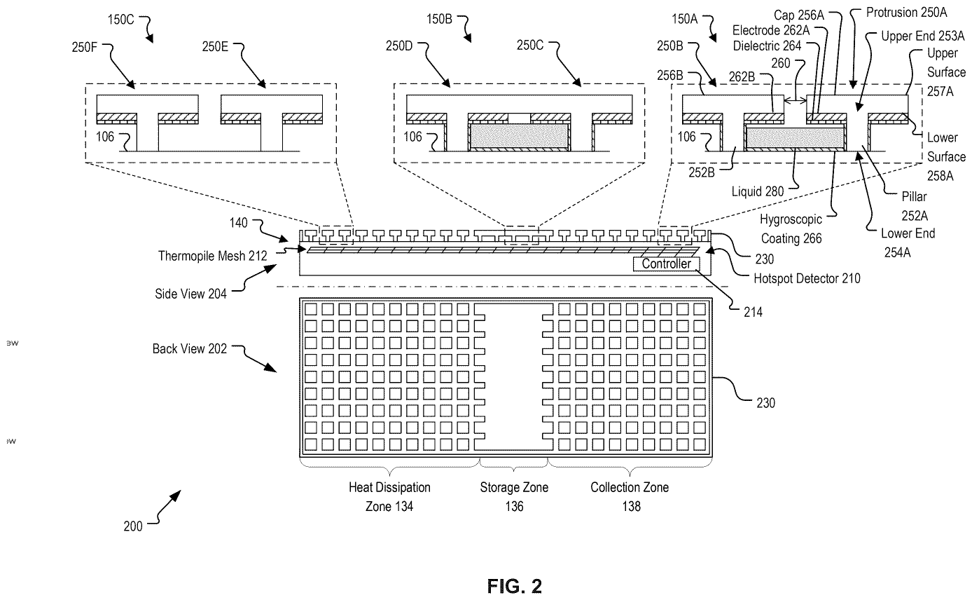

The heat dissipation mechanism 140 is integrated in the cover 102 and configured to evaporatively cool the portable electronic device 120. According to an aspect, the heat dissipation mechanism 140 includes numerous micropillar structures corresponding to liquid retention structures (e.g., microstructures and/or nanostructures) that can retain water film within the structures while avoiding leakage outside the structures, thereby avoiding user discomfort from contact with water or moisture at the back surface 106. To illustrate, the heat dissipation mechanism 140 includes a set of liquid retention structures 150 located at the outer surface 106. The heat dissipation mechanism 140 also includes a set of electrodes coupled to the set of liquid retention structures 150 and configured to enable transport of liquid (e.g., water collected from the atmosphere) to and from various locations at the back surface 106 of the portable electronic device 120, as described in further detail with reference to FIG. 2. According to an aspect, the heat dissipation mechanism 140 is configured to transport the liquid via an electrowetting technology, such as electrowetting-on-dielectric (EWOD), as described in further detail in FIG. 2.

A first portion of the set of liquid retention structures 150 are included in a heat dissipation zone 134, a second portion of the set of liquid retention structures 150 are included in a storage zone 136, and a third portion of the set of liquid retention structures 150 are included in a collection zone 138. The collection zone 138 is used for absorption of atmospheric moisture, which can then be transported to the storage zone 136 and to the heat dissipation zone 134. According to an aspect, the liquid retention structures 150 in the collection zone 138 include a coating or layer of a hygroscopic material that is capable of absorbing moisture from atmospheric air. Once collected, the resulting water droplets or film can be transported to the storage zone 136 using electrowetting technology to propel the water droplets by alternatively actuating adjacent electrodes of the liquid retention structures 150. An example architecture of the liquid retention structures 150 in the collection zone 138, such as a representative liquid retention structure 150A, is described in further detail with reference to FIG. 2.

The storage zone 136 is used to store the water that is collected from the collection zone 138, until transported by the heat dissipation mechanism 140 to the heat dissipation zone 134. An example architecture of the liquid retention structures 150 in the storage zone 136, such as a representative liquid retention structure 150B, is described in further detail with reference to FIG. 2.

The heat dissipation zone 134 is located at the top half of the back surface 106 because this region of the back surface 106 tends to be hotter due to its proximity to the integrated circuit 124. As compared to the liquid retention structures 150 in the collection zone 138, the liquid retention structures 150 in the heat dissipation zone 134 may omit the hygroscopic material to improve evaporation efficiency. An example architecture of the liquid retention structures 150 in the heat dissipation zone 134, such as a representative liquid retention structure 150C, is described in further detail with reference to FIG. 2.

During operation, the heat dissipation mechanism 140 enables targeted hotspot reduction by transporting the liquid between locations of the outer surface 106 using an electrowetting technique that includes selective application of electrical biases to the electrodes of the liquid retention structures 150. To illustrate, the water that is collected in the collection zone 138 can be transported into the storage zone 136, where water is accumulated until transported out of the storage zone 136 upon detection of one or more hotspots in the heat dissipation zone 134.

In a particular embodiment, the heat dissipation mechanism 140 includes a hotspot detector that is coupled to the cover 102 and configured to detect temperatures at various locations at the back surface 106. For example, the heat dissipation mechanism 140 can detect that a first temperature (T1) 182 at a first location 180 (e.g., in the storage zone 136) is lower than a second temperature (T2) 186 at a second location 184 (e.g., a first hotspot 108A in the heat dissipation zone 134), and may cause the transport of water from the first location 180 to the second location 184, such as via an exemplary electrowetting path 160 along selected liquid retention structures 150 on the back surface 106.

According to some aspects, the control system-based heat dissipation mechanism 140 compares the detected temperatures to one or more thresholds and initiates water transport based on the comparison(s). According to one example, the heat dissipation mechanism 140 initiates transport of water to a hotspot in response to detecting that the temperature at the hotspot matches or exceeds a skin temperature threshold (e.g., 45° C.). According to another example, the heat dissipation mechanism 140 initiates transport of water to a hotspot in response to detecting that the temperature at the hotspot matches or exceeds a second threshold (e.g., 43° C.) that is lower than the skin temperature threshold (e.g., 45° C.) to prevent the hotspot from reaching the skin temperature threshold. For example, the heat dissipation mechanism 140 may detect the first hotspot 108A at the second location 184 and a second hotspot 108B at a third location 188 based on temperatures at the second location 184 and the third location 188 exceeding the second threshold. As a result, the heat dissipation mechanism 140 may initiate the transport of water from the first location 180 (e.g., the storage zone 136) to the second location 184 via the electrowetting path 160 and to the third location 188 via another electrowetting path 162. The resulting fluid transport (e.g., electrophoretic transport) enables targeted hotspot reduction and/or prevention, conserving water as compared to evaporative cooling mechanisms that cool an entire surface, and therefore improves overall performance by reducing or eliminating the amount of throttling that would otherwise be needed to prevent a skin temperature threshold from being exceeded.

Thus, FIG. 1 illustrates an example of a portable electronic device (e.g., the portable electronic device 120) that includes a display panel (e.g., the display panel 122) at a front surface (e.g., the front surface 104) of the portable electronic device (e.g., the portable electronic device 120). The portable electronic device (e.g., the portable electronic device 120) includes an integrated circuit (e.g., the integrated circuit 124) coupled to the display panel (e.g., the display panel 122). The portable electronic device (e.g., the portable electronic device 120) also includes a cover (e.g., the cover 102) coupled to the integrated circuit (e.g., the integrated circuit 124) at a back surface (e.g., the back surface 106) of the portable electronic device (e.g., the portable electronic device 120).

In this example, the portable electronic device (e.g., the portable electronic device 120) further includes a heat dissipation mechanism (e.g., the heat dissipation mechanism 140) integrated in the cover (e.g., the cover 102) and configured to evaporatively cool the portable electronic device (e.g., the portable electronic device 120). In this example, the heat dissipation mechanism (e.g., the heat dissipation mechanism 140) includes a set of liquid retention structures (e.g., the liquid retention structures 150) located at the back surface (e.g., the back surface 106) and also includes a set of electrodes coupled to the set of liquid retention structures (e.g., the liquid retention structures 150) and configured to enable transport of liquid at the liquid retention structures (e.g., the liquid retention structures 150) from a first location (e.g., the first location 180) of the back surface (e.g., the back surface 106) to a second location (e.g., the second location 184) of the back surface (e.g., the back surface 106).

In some embodiments of this example, the heat dissipation mechanism (e.g., the heat dissipation mechanism 140) is configured to transport the liquid via electrowetting.

In some embodiments of this example, the heat dissipation mechanism (e.g., the heat dissipation mechanism 140) is configured to transport the liquid from the first location (e.g., the first location 180) having a first temperature (e.g., the first temperature (T1) 182) to the second location (e.g.., the second location 184) having a second temperature (e.g., the second temperature (T2) 186), wherein the second temperature (e.g., the second temperature (T2) 186) is higher than the first temperature (e.g., the first temperature (T1) 182) due to heat generation of the integrated circuit (e.g., the integrated circuit 124).

In some embodiments of this example, the set of liquid retention structures (e.g., the liquid retention structures 150) includes nanostructures.

FIG. 1 also illustrates an example of a device (e.g., the device 100) that includes a cover (e.g., the cover 102) configured to provide an outer surface (e.g., the back surface 106) of a portable electronic device (e.g., the portable electronic device 120). The device (e.g., the device 100) also includes a heat dissipation mechanism (e.g., the heat dissipation mechanism 140) integrated in the cover (e.g., the cover 102) and configured to evaporatively cool the portable electronic device (e.g., the portable electronic device 120). The heat dissipation mechanism (e.g., the heat dissipation mechanism 140) includes a set of liquid retention structures (e.g., the liquid retention structures 150) located at the outer surface (e.g., the back surface 106). The heat dissipation mechanism (e.g., the heat dissipation mechanism 140) also includes a set of electrodes coupled to the set of liquid retention structures (e.g., the liquid retention structures 150) and configured to enable transport of liquid at the liquid retention structures (e.g., the liquid retention structures 150) from a first location (e.g., the first location 180) of the outer surface (e.g., the back surface 106) to a second location (e.g., the second location 184) of the outer surface (e.g., the back surface 106).

In some embodiments of this example, the heat dissipation mechanism (e.g., the heat dissipation mechanism 140) is configured to transport the liquid via electrowetting.

In some embodiments of this example, the heat dissipation mechanism (e.g., the heat dissipation mechanism 140) is configured to transport the liquid from the first location (e.g., the first location 180) having a first temperature (e.g., the first temperature (T1) 182) to the second location (e.g., the second location 184) having a second temperature (e.g., the second temperature (T2) 186) that is higher than the first temperature (e.g., the first temperature (T1) 182).

In some embodiments of this example, a first portion of the set of liquid retention structures (e.g., the liquid retention structures 150) are included in a thermal dissipation zone (e.g., the heat dissipation zone 134) and a second portion of the set of liquid retention structures (e.g., the liquid retention structures 150) are included in a storage zone (e.g., the storage zone 136). A third portion of the set of liquid retention structures (e.g., the liquid retention structures 150) can be included in a collection zone (e.g., the collection zone 138).

FIG. 2 illustrates a schematic back view and cross-sectional profile view, depicted as a back view 202 and a side view 204, respectively, of an exemplary device 200 that includes a heat dissipation mechanism configured to perform evaporative cooling. The device 200 of FIG. 2 includes many of the same components and features as are described above with reference to FIG. 1. Such components and features are physically and operationally the same as described above with reference to FIG. 1 and are labeled in FIG. 2 using the same reference numbers. In some implementations, the device 200 corresponds to the device 100 of FIG. 1 (e.g., the cover 102 and/or the portable electronic device 120 including the cover 102) and includes all of the same features and components as the device 100 of FIG. 1.

FIG. 2 also illustrates example architectures of the liquid retention structures 150 of the heat dissipation mechanism 140, including the representative liquid retention structure 150A of the collection zone 138, the representative liquid retention structure 150B of the storage zone 136, and the representative liquid retention structure 150C of the heat dissipation zone 134.

As illustrated, the representative liquid retention structure 150A of the collection zone 138 includes a first protrusion 250A and a second protrusion 250B that extend outward from the back surface 106. In a particular embodiment, the first protrusion 250A and the second protrusion 250B are nanostructures (e.g., have one or more features with dimensions approximately on the order of 1 nanometer). Alternatively, in another particular embodiment, the first protrusion 250A and the second protrusion 250B are microstructures (e.g., have one or more features with dimensions approximately on the order of 1 micrometer).

The first protrusion 250A includes a first pillar 252A having an upper end 253A and a lower end 254A. The lower end 254A of the first pillar 252A is coupled to the outer surface 106. The first protrusion 250A also includes a first cap portion 256A that has an upper surface 257A and a lower surface 258A. The lower surface 258A of the first cap portion 256A is coupled to the upper end 253A of the first pillar 252A.

Similarly, the second protrusion 250B includes a second pillar 252B having an upper end that is coupled to a second cap portion 256B and a lower end that is coupled to the outer surface. The second cap portion 256B also has an upper surface and a lower surface, with the lower surface of the second cap portion 256B being coupled to the upper end of the second pillar 252B.

The first protrusion 250A and the second protrusion 250B—more particularly, adjacent edges of the first cap portion 256A and the second cap portion 256B—are separated by a spacing 260. The spacing 260 is selected to be large enough to enable entry of atmospheric moisture into the space between the protrusions 250A and 250B, but small enough to enable the retention of liquid 280 in the space between the first protrusion 250A and the second protrusion 250B. According to an aspect, the spacing 260 corresponds to an interpillar spacing (as seen in the back view 202) that can be calculated so that the surface tension of a water droplet within the liquid retention structure 150A balances the weight of the droplet, preventing (or substantially reducing) leaking of water out through the spacing 260 due to gravity when the back surface 106 is facing downward, and to prevent leaking onto a user's hand when the user's hand is in contact with the upper surfaces 257 of the cap portions 256. According to some embodiments, a barrier 230 is also provided at a perimeter of the collection zone 138, the storage zone 136, and/or the heat dissipation zone 134 to prevent the liquid in the liquid retention structures 150 from exiting along the edges of the device 200.

To enable transport of water between liquid retention structures 150, a first electrode 262A is coupled to the lower surface 258A of the first cap portion 256A, and a second electrode 262B is coupled to the lower surface of the second cap portion 256B. As illustrated, each of the first electrode 262A and the second electrode 262B is coated with a dielectric material 264 that permits an electric field but that prevents (or substantially prevents) current flow between the first electrode 262A and the second electrode 262B when the height of the liquid 280 reaches the lower surfaces 258 of the cap portions 256. As a result, water transport between liquid retention structures 150 can be performed using an electrowetting-on-dielectric technique to convey droplets collected in liquid retention structures 150 of the collection zone 138 to the storage zone 136.

According to an aspect, the electrowetting-on-dielectric technique to transport water between liquid retention structures 150 is performed by applying a first electric potential (e.g., a positive voltage) to one or more first electrodes 262 on a protrusion 250 at a first side of a droplet and applying a second electric potential (e.g., a ground voltage) to one or more second electrodes 262 at a second side of the droplet, resulting in motion of the droplet toward the first electrodes 262 having the first electric potential and away from the second electrodes 262 having the second electric potential. Electrowetting on dielectric has been demonstrated using relatively low voltages (e.g., less than 8 volts), so that water transport can be performed given the power constraints of portable devices and using sufficiently low voltages to not pose a potential electrical shock risk to users of such devices. As voltages used for electrowetting are further reduced due to technology improvements, such power and safety advantages are further enhanced.

The liquid retention structure 150A also includes a hygroscopic coating 266 on one or more surfaces of the liquid retention structure 150A to help absorb water from the atmosphere for collection within the liquid retention structure 150A. For example, the hygroscopic coating 266 can be formed of a hygroscopic material that is deposited or formed on a portion of the back surface 106 that is between the first protrusion 250A and the second protrusion 250B, a sidewall of the first protrusion 250A, a sidewall of the second protrusion 250B, or a combination thereof. In a particular embodiment, the hygroscopic coating 266 corresponds to or includes a hydrophilic polymer. For example, the hygroscopic coating 266 may correspond to a temperature sensitive polymer with a surface property that switches from hydrophilic to hydrophobic at a particular threshold temperature, which could facilitate absorption and transportation at a different temperature range. In an illustrative, non-limiting example, the hygroscopic coating 266 includes a combination of cotton and Poly(N-isopropylacrylamide) (PNIPAAm).

The liquid retention structure 150B of the storage zone 136 includes a third protrusion 250C and a fourth protrusion 250D that extend outward from the back surface 106. In a particular embodiment, the third protrusion 250C and the fourth protrusion 250D correspond to the first protrusion 250A and the second protrusion 250B, respectively, of the liquid retention structure 150A in the collection zone 138 and include electrodes 262, dielectric material 264, and a hygroscopic coating 266 as described for the liquid retention structure 150A. However, in contrast to the liquid retention structure 150A, the liquid retention structure 150B of the storage zone 136 has a reduced spacing 260 between adjacent cap portions 256 to reduce fluid loss, such as due to evaporation through the spacing 260 between the adjacent cap portions 256. In the illustrated example of the liquid retention structure 150B, the spacing 260 is zero, e.g., the cap portions 256 of adjacent protrusions 250 form a continuous roof or canopy structure that can span across multiple liquid retention structures 150 in the storage zone 136. Such a continuous roof structure is depicted in the back view 202 by the absence of the distinct cap portions 256 that are depicted in the collection zone 138 and the heat dissipation zone 134. Although the spacing 260 in the storage zone 136 is depicted as zero (e.g., the cap portions form a continuous roof structure), in other embodiments the spacing 260 can be non-zero (e.g., having gaps between adjacent cap portions 256) in the storage zone 136.

The liquid retention structure 150C of the heat dissipation zone 134 includes a fifth protrusion 250E and a sixth protrusion 250F that extend outward from the back surface 106. In a particular embodiment, the fifth protrusion 250E and the sixth protrusion 250F correspond to the first protrusion 250A and the second protrusion 250B, respectively, of the liquid retention structure 150A in the collection zone 138 and include electrodes 262 and dielectric material 264 as described for the liquid retention structure 150A. However, in contrast to the liquid retention structure 150A, the liquid retention structure 150C of the heat dissipation zone 134 omits the hygroscopic coating 266 to facilitate evaporation of fluid transported to the liquid retention structure 150C for heat dissipation.

The device 200 also includes a hotspot detector 210 coupled to the cover 102 and configured to detect locations of hotspots at the back surface 106. In a particular embodiment, the hotspot detector 210 includes a thermopile mesh 212 coupled to a controller 214. To illustrate, the thermopile mesh 212 can include a grid or array of conductors, such as a first set of wires of a first material extending in a first direction and a second set of wires extending in a second direction, such as first wires that extend along rows of the protrusions 250 and second wires that extend along columns of the protrusions 250, forming thermocouples at the intersections of the first wires and the second wires. Voltages at the periphery terminals of each of the wires are measured to determine, at the controller 214, relative temperatures at each intersection (e.g., at the location of each protrusion 250 or liquid retention structure 150).

The controller 214 is configured to receive and process temperature measurement input (e.g., voltage measurements from the periphery terminals of the thermopile mesh 212) to determine absolute temperatures, hotspot locations, or a combination thereof, associated with each protrusion 250 or liquid retention structure 150. According to an aspect, the controller 214 is configured to compare a temperature value of each of the protrusions 250 or liquid retention structures 150 to a threshold (e.g., a skin temperature threshold or a second threshold that is lower than the skin temperature threshold) to determine whether that protrusion 250 or liquid retention structure 150 corresponds to a hotspot. In some embodiments, hotspots are expected to only form in one or more subsections of the back surface 106, such as in the heat dissipation zone 134 but not in the storage zone 136 or the collection zone 138. In such embodiments, the thermopile mesh 212 can be limited to locations corresponding to the one or more subsections, and hotspot detection operations of the controller 214 can also be limited to the protrusions 250 or liquid retention structures 150 corresponding to the one or more subsections, thus reducing the fabrication cost, complexity, and power consumption associated with operation of the hotspot detector 210.

The controller 214 is also electrically coupled to the electrodes 262 of the liquid retention structures 150 and configured to implement a control system to direct operations of the heat dissipation mechanism 140 to transport fluid from the collection zone 138 to the storage zone 136, and from the storage zone 136 to detected hotspots in the heat dissipation zone 134. To illustrate, the controller 214 is configured to adjust electrical voltages at selected electrodes 262 to detect the presence of droplets of the liquid 280 at liquid retention structures 150 in the collection zone 138 and to transport, merge, split, coalesce, or otherwise manipulate the droplets of the liquid 280. For example, the controller 214 is configured to detect an amount of the liquid 280 in the liquid retention structure 150A based on an amount of capacitance and/or resistance between the first electrode 262A and the second electrode 262B. To illustrate, in some embodiments a capacitance between the first electrode 262A and the second electrode 262B is lowest in the absence of liquid in the liquid retention structure 150A and is highest when the level of the liquid 280 reaches the dielectric material 264. Similarly, a resistance between the first electrode 262A and the second electrode 262B is lowest when the liquid 280 in the liquid retention structure 150A is in contact with the first electrode 262A and the second electrode 262B.

During operation, water is collected from the atmosphere in the liquid retention structures 150 of the collection zone 138 and transported to the storage zone 136. For example, the controller 214 continuously, periodically, or occasionally scans the liquid retention structures 150 of the collection zone 138, e.g., by measuring inter-electrode capacitance or resistance, to detect an amount of collected liquid 280 in each liquid retention structure 150. In response to detecting a sufficient amount of the collected liquid 280 in one or more of the liquid retention structures 150, the controller 214 issues control signals to actuate the electrodes 262 in an alternating fashion to move the droplets toward, and into, the storage zone 136, such as in a manner analogous to a digital microfluidics technique. In some embodiments, water can also be artificially injected into the storage zone 136 by a user to provide additional cooling capacity, such as for intense workloads of the device 200 (e.g., extended gaming and generative artificial intelligence (AI) inference-based use cases).

The control system implemented at the controller 214 also transports the liquid from the storage zone 136 to the dissipation zone 134 for device cooling. To illustrate, the controller 214 can perform targeted hotspot reductions on the back surface 106 by targeting higher water transport rates to the areas which are known to be hotter than others, such as via temperature and/or hotspot detection by the hotspot detector 210. To illustrate, the thermopile mesh 212 at the back surface 106 of the device 200 can be used to detect hotspot locations with relatively high spatial granularity, further increasing the efficiency of spatial targeted cooling. The transport rate of liquid to the dissipation zone, and the specific destination of the liquid can also depend on the skin temperature (T_skin) at each detected hotspot and the rate at which the temperature is increasing at each detected hotspot, with higher detected temperature excursions resulting in the controller 214 directing higher flow rates of the liquid for enhanced evaporative cooling. In a particular example, a fluid transport rate to each of one or more hotspot locations is determined by a proportional-integral-derivative (PID)-type control process executed at the controller 214 to provide continuous control and automatic adjustment in a closed-loop operation. An input corresponding to temperature values at each of the liquid retention structures 150 or protrusions 250 at the hotspot locations can be continually monitored, and a fluid transfer rate can be an output parameter of the control process.

Thus, FIG. 2 illustrates an example of a device (e.g., the device 200) that includes a cover (e.g., the cover 102) configured to provide an outer surface (e.g., the back surface 106) of a portable electronic device (e.g., the portable electronic device 120). The device (e.g., the device 100) also includes a heat dissipation mechanism (e.g., the heat dissipation mechanism 140) integrated in the cover (e.g., the cover 102) and configured to evaporatively cool the portable electronic device (e.g., the portable electronic device 120). The heat dissipation mechanism (e.g., the heat dissipation mechanism 140) includes a set of liquid retention structures (e.g., the liquid retention structures 150) located at the outer surface (e.g., the back surface 106). The heat dissipation mechanism (e.g., the heat dissipation mechanism 140) also includes a set of electrodes (e.g., the electrodes 262) coupled to the set of liquid retention structures (e.g., the liquid retention structures 150) and configured to enable transport of liquid (e.g., the liquid 280) at the liquid retention structures (e.g., the liquid retention structures 150) from a first location (e.g., the first location 180) of the outer surface (e.g., the back surface 106) to a second location (e.g., the second location 184) of the outer surface (e.g., the back surface 106).

In some embodiments of this example, the heat dissipation mechanism (e.g., the heat dissipation mechanism 140) is configured to transport the liquid (e.g., the liquid 280) via electrowetting.

In some embodiments of this example, the heat dissipation mechanism (e.g., the heat dissipation mechanism 140) is configured to transport the liquid (e.g., the liquid 280) from the first location (e.g., the first location 180) having a first temperature (e.g., the first temperature (T1) 182) to the second location (e.g., the second location 184) having a second temperature (e.g., the second temperature (T2) 186) that is higher than the first temperature (e.g., the first temperature (T1) 182).

In some embodiments of this example, the set of liquid retention structures (e.g., the liquid retention structures 150) includes a plurality of protrusions (e.g., the protrusions 250) extending outward from the outer surface (e.g., the back surface 106), and a spacing (e.g., the spacing 260) between a first protrusion (e.g., the first protrusion 250A) of the plurality of protrusions and a second protrusion (e.g., the second protrusion 250B) of the plurality of protrusions that is adjacent to the first protrusion (e.g., the first protrusion 250A) enables retention of water between the first protrusion (e.g., the first protrusion 250A) and the second protrusion (e.g., the second protrusion 250B). The first protrusion (e.g., the first protrusion 250A) and the second protrusion (e.g., the second protrusion 250B) can be nanostructures.

In some such embodiments of this example, the first protrusion (e.g., the first protrusion 250A) can include a first pillar (e.g., the first pillar 252A) having an upper end (e.g., the upper end 253A) and a lower end (e.g., the lower end 254A), wherein the lower end (e.g., the lower end 254A) of the first pillar (e.g., the first pillar 252A) is coupled to the outer surface (e.g., the back surface 106), and the first protrusion (e.g., the first protrusion 250A) can also include a first cap portion (e.g., the first cap portion 256A) having an upper surface (e.g., the upper surface 257A) and a lower surface (e.g., the lower surface 258A), wherein the lower surface (e.g., the lower surface 258A) of the first cap portion (e.g., the first cap portion 256A) is coupled to the upper end (e.g., the upper end 253A) of the first pillar (e.g., the first pillar 252A). The second protrusion (e.g., the second protrusion 250B) can include a second pillar (e.g., the second pillar 252B) having an upper end and a lower end, wherein the lower end of the second pillar (e.g., the second pillar 252B) is coupled to the outer surface (e.g., the back surface 106), and the second protrusion (e.g., the second protrusion 250B) can include a second cap portion (e.g., the second cap portion 256B) having an upper surface and a lower surface, wherein the lower surface of the second cap portion (e.g., the second cap portion 256B) is coupled to the upper end of the second pillar (e.g., the second pillar 252B).

In some such embodiments of this example, a first electrode (e.g., the first electrode 262A) of the set of electrodes (e.g., the electrodes 262) is coupled to the lower surface (e.g., the lower surface 258A) of the first cap portion (e.g., the first cap portion 256A), and a second electrode (e.g., the second electrode 262B) of the set of electrodes (e.g., the electrodes 262) is coupled to the lower surface of the second cap portion (e.g., the second cap portion 256B). Each of the first electrode (e.g., the first electrode 262A) and the second electrode (e.g., the second electrode 262B) is coated with a dielectric material (e.g., the dielectric material 264).

In some embodiments of this example, the set of liquid retention structures (e.g., the liquid retention structures 150) includes a hygroscopic coating (e.g., the hygroscopic coating 266A) on at least one of: a portion of the outer surface (e.g., the back surface 106) that is between the first protrusion (e.g., the first protrusion 250A) and the second protrusion (e.g., the second protrusion 250B); a sidewall of the first protrusion (e.g., the first protrusion 250A); or a sidewall of the second protrusion (e.g., the second protrusion 250B).

In some embodiments of this example, the device (e.g., the device 200) further includes a hotspot detector (e.g., the hotspot detector 210) coupled to the cover (e.g., the cover 102) and configured to detect locations (e.g., the second location 184, the third location 188) of hotspots (e.g., the first hotspot 108A, the second hotspot 108B) at the outer surface (e.g., the back surface 106), and wherein the heat dissipation mechanism (e.g., the heat dissipation mechanism 140) is configured to transport liquid (e.g., the liquid 280) to the detected locations (e.g., the second location 184, the third location 188) of the hotspots (e.g., the first hotspot 108A, the second hotspot 108B). The hotspot detector (e.g., the hotspot detector 210) can include a thermopile mesh (e.g., the thermopile mesh 212).

In some embodiments of this example, a first portion of the set of liquid retention structures (e.g., the liquid retention structures 150) are included in a thermal dissipation zone (e.g., the heat dissipation zone 134) and a second portion of the set of liquid retention structures (e.g., the liquid retention structures 150) are included in a storage zone (e.g., the storage zone 136). A third portion of the set of liquid retention structures (e.g., the liquid retention structures 150) can be included in a collection zone (e.g., the collection zone 138).

It should be understood that the device 100, the cover 102, the device 200, or any combination thereof may include additional components, other components, fewer components, or a combination thereof, to support the functionality described herein. As non-limiting examples, the device 100, the device 200, or both, may include additional dies, additional packaged IC devices, additional interconnects, additional structures, other components, different components, or a combination thereof, to support the functionality and technical advantages disclosed herein.

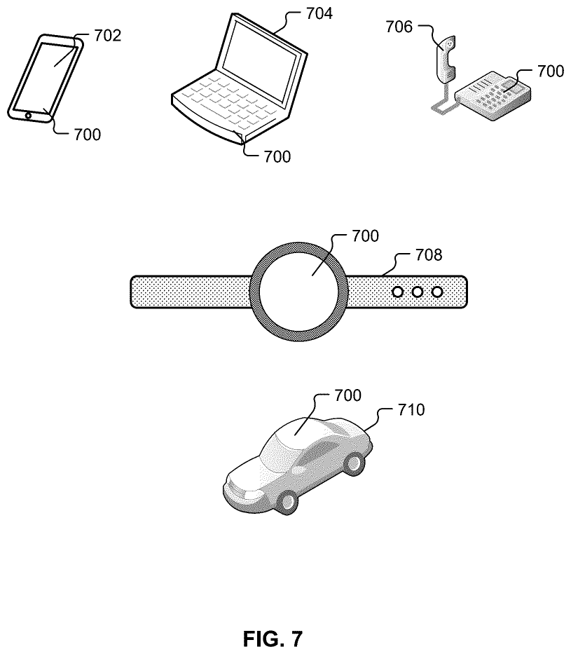

In various examples, the control system-based heat dissipation mechanism 140, can be integrated in a smartphone, a tablet computer, a fixed location terminal device, an automobile, a wearable electronic device, a laptop computer, or some combination thereof, as described in more detail below with reference to FIG. 7. Further, the heat dissipation mechanism 140 can be integrated with or included within a wide variety of other devices. For example, a device that includes the heat dissipation mechanism 140 can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the heat dissipation mechanism 140 can operate to cool any of these components (or a combination of these components) that includes active circuitry.

Although the back view 202 and the side view 204 schematically depict an arrangement of the protrusion 250 on the back surface 106, with intervening gaps between adjacent protrusions 250, it should be understood that the protrusions 250 and the intervening gaps are not necessarily drawn to scale. Although the cap portions 256 are illustrated as having a square shape in the back view 202, the cap portions 256 need not be square and, in other embodiments, can have any other shape such as rectangles, triangles, hexagons, or any other shape or combination of shapes that can be used in a tessellation or tiling to substantially cover one or more portions, or all, of the back surface 106.

Although the controller 214 is depicted coupled to the thermopile mesh 212 and configured to detect hotspot locations (e.g., as a set of (row, column) values of each protrusion 250 or liquid retention structure 150 coinciding with each hotspot), in other embodiments the hotspot detector 210 (e.g., an output of the thermopile mesh 212) is instead electrically coupled to an integrated circuit of the portable electronic device 120, such as the integrated circuit 124, which performs detection of the hotspot locations and outputs control signals to transport fluid, as described above, such as from the storage zone 136 to the hotspot locations in the heat dissipation zone 134.

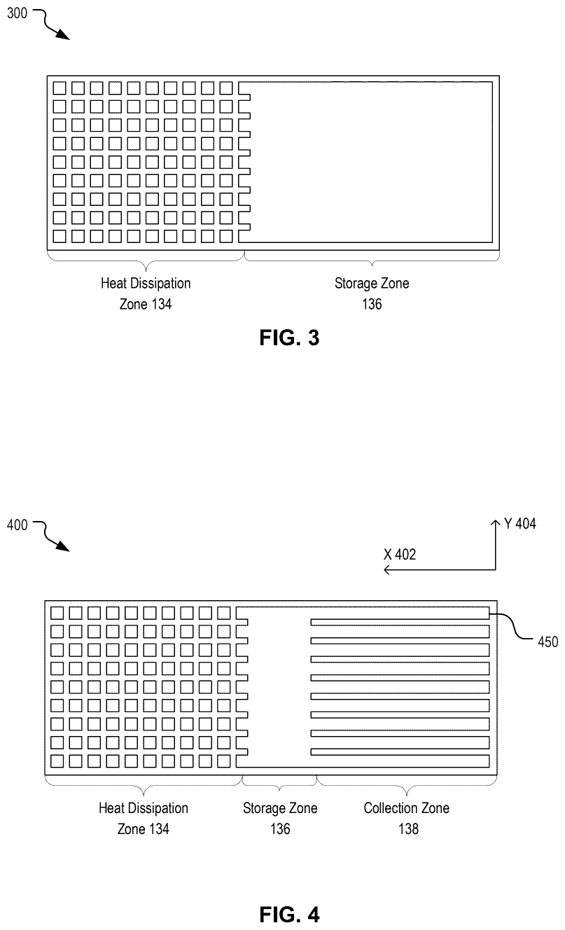

FIG. 3 illustrates a schematic back view of an exemplary device 300 that includes a heat dissipation mechanism configured to perform evaporative cooling. The device 300 of FIG. 3 includes many of the same components and features as are described above with reference to FIG. 1, FIG. 2, or both. Such components and features are physically and operationally the same as described above with reference to FIG. 1 and FIG. 2 and are labeled in FIG. 3 using the same reference numbers. In some implementations, the device 300 corresponds to the device 100 of FIG. 1 (e.g., the cover 102 and/or the portable electronic device 120 including the cover 102) and includes all of the same features and components as the device 100 of FIG. 1. In some implementations, the device 300 corresponds to the device 200 of FIG. 2 and includes all of the same features and components as the device 200 of FIG. 2.

The device 300 includes an alternative architecture that includes the heat dissipation zone 134 and the storage zone 136 but omits the collection zone 138 of FIG. 1 and FIG. 2. Instead of collecting moisture from the atmosphere using the hygroscopic coating 266 of FIG. 2, the device 300 can receive fluid (e.g., water, methanol, ethanol, etc.) that is manually inserted by a user into the storage zone 136 (e.g., at a perimeter of the storage zone 136 where liquid can be injected beneath the continuous roof structure), such as via use of a dropper, as an illustrative, non-limiting example.

FIG. 4 illustrates a schematic back view of an exemplary device 400 that includes a heat dissipation mechanism configured to perform evaporative cooling. The device 400 of FIG. 4 includes many of the same components and features as are described above with reference to FIG. 1, FIG. 2, or both. Such components and features are physically and operationally the same as described above with reference to FIG. 1 and FIG. 2 and are labeled in FIG. 4 using the same reference numbers. In some implementations, the device 400 corresponds to the device 100 of FIG. 1 (e.g., the cover 102 and/or the portable electronic device 120 including the cover 102) and includes all of the same features and components as the device 100 of FIG. 1. In some implementations, the device 400 corresponds to the device 200 of FIG. 2 and includes all of the same features and components as the device 200 of FIG. 2.

The device 400 illustrates an alternative architecture in which one or more portions of the liquid retention structures 150 form channels, illustrated in the collection zone 138 as extending from a right edge of the device 400 to the storage zone 136. For example, because fluid collected in the collection zone 138 can be transported directly to the storage zone 136 via movement in an X direction 402 without needing to be moved in a Y direction 404, elongated protrusions 450 in the collection zone 138 can each be formed as a continuous wall structure (rather than as a sequence of multiple pillars 252 as in FIG. 2), with channels being formed between adjacent wall structures. Each of the elongated protrusions 450 extends for substantially the length of the collection zone 138 in the X direction 402 and is capped with a rectangular cap portion that also extends for substantially the length of the collection zone 138 in the X direction 402.

The electrodes 262 and the dielectric material 264 of FIG. 2 are coupled to the lower surface of the cap portion of each elongated protrusion 450 and positioned at regular intervals along the length of the elongated protrusions 450 to enable transport of fluid in the X direction 402 via alternating voltages on the electrodes 262 in a similar manner as described for FIG. 2. The hygroscopic coating 266 can be formed on the surface of the device 400 between adjacent walls structures, on the wall surfaces of the wall structures (e.g., covering the wall structure from surface of the device 400 to the cap structure), or both, and along the entire length of the channel between adjacent elongated protrusions 450. As a result, the collection zone 138 may include a larger surface area of the hygroscopic coating 266 for larger moisture collection capacity as compared to the device 200 of FIG. 2, with reduced complexity as compared to the device 200 due to transporting the collected fluid directly along the channels and into the storage zone 136.

### Exemplary Flow Diagram of a Method for Operating a Device Including a Heat Dissipation Mechanism for Evaporative Cooling

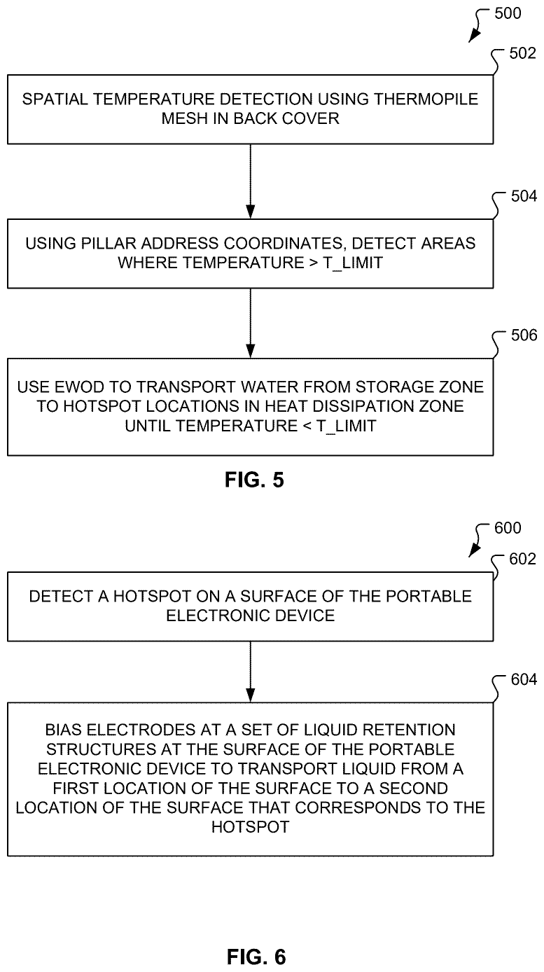

In some implementations, operating a device that includes a heat dissipation mechanism for evaporative cooling includes several processes. FIG. 5 illustrates an exemplary flow diagram of a method of cooling a portable electronic device. In a particular aspect, one or more operations of the method 500 are initiated, performed, or controlled by one or more processors of the portable electronic device or of a controller coupled to the portable electronic device. In some implementations, operations of the method 500 may be stored as instructions at a non-transitory computer-readable storage medium, and the instructions may be executable by one or more processors to cause the one or more processors to perform operations of the method 500. In some implementations, the method 500 of FIG. 5 may be performed by the integrated circuit 124 (e.g., a processor in the first chip 125A executing computer-readable instructions that are stored in a memory in the second chip 125B), the heat dissipation mechanism 140, the liquid retention structures 150, the hotspot detector 210, the thermopile mesh 212, the controller 214, or a combination thereof.

It should be noted that the method 500 of FIG. 5 may combine one or more processes in order to simplify and/or clarify the method for cooling a portable electronic device. In some implementations, the order of the processes may be changed or modified.

The method 500 includes, at block 502, spatial temperature detection using a thermopile mesh in a back cover of the portable electronic device. For example, the hotspot detector 210 of FIG. 2 can perform temperature detection at various locations in the heat dissipation zone 134 based on voltages detected at the peripheral ends of wires of the thermopile mesh 212.

The method 500 includes, at block 504, using pillar address coordinates, detecting areas where a temperature exceeds a temperature threshold (T_limit). For example, the conductors of the thermopile mesh 212 can be arranged such that the conductors intersect at the location of each of the pillars 252 in the heat dissipation zone 134, and the hotspot detector 210 (e.g., the controller 214, the integrated circuit 124, or both) can perform a temperature detection operation for each intersection according to a (row, column) address coordinate system associated with the pillars 252. The hotspot detector 210 (e.g., the controller 214, the integrated circuit 124, or both) can compare each detected temperature to the threshold temperature, and the pillar address coordinates associated with each detected temperature that exceeds the threshold temperature (e.g., a skin temperature threshold) can be identified as a hotspot location.

The method 500 includes, at block 506, using an electrowetting-on-dielectric technique to transport water from a storage zone to detected hotspot locations in a heat dissipation zone until the temperature at each hotspot location is below the threshold temperature. For example, the hotspot detector 210 (e.g., the controller 214, the integrated circuit 124, or both) can select one or more electrowetting paths to transport water from the storage zone 136 to the hotspots locations in the heat dissipation zone 134. To illustrate, the hotspot detector 210 (e.g., the controller 214, the integrated circuit 124, or both) can select the electrowetting path 160 of FIG. 1 and generate control signals to apply a sequence of alternating voltage biases to the electrodes 262 at the liquid retention structures 150 along the electrowetting path 160 of FIG. 1 to transport water from the storage zone 136 to the first hotspot 108A at the second location 184. The hotspot detector 210 (e.g., the controller 214, the integrated circuit 124, or both) can also select the electrowetting path 162 of FIG. 1 and generate control signals to apply a sequence of alternating voltage biases to the electrodes 262 at the liquid retention structures 150 along the electrowetting path 162 to transport water from the storage zone 136 to the second hotspot 108B at the third location 188. The hotspot detector 210 can continuously, periodically, or occasionally repeat the temperature detection operations at the hotspot locations and the comparisons to the threshold temperature for each of the pillar addresses corresponding to the hotspot locations, and cease the transport of water to locations that have been sufficiently cooled and no longer qualify as a hotspot (e.g., when the detected temperature falls below T_limit).

FIG. 6 illustrates another exemplary flow diagram of a method of cooling a portable electronic device. In a particular aspect, one or more operations of the method 600 are initiated, performed, or controlled by one or more processors of the portable electronic device or of a controller coupled to the portable electronic device. In some implementations, operations of the method 600 may be stored as instructions at a non-transitory computer-readable storage medium, and the instructions may be executable by one or more processors to cause the one or more processors to perform operations of the method 600. In some implementations, the method 600 of FIG. 6 may be performed by the integrated circuit 124 (e.g., a processor in the first chip 125A executing computer-readable instructions that are stored in a memory in the second chip 125B), the heat dissipation mechanism 140, the liquid retention structures 150, the hotspot detector 210, the thermopile mesh 212, the controller 214, or a combination thereof.

It should be noted that the method 600 of FIG. 6 may combine one or more processes in order to simplify and/or clarify the method for cooling a portable electronic device. In some implementations, the order of the processes may be changed or modified.

The method 600 includes, at block 602, detecting a hotspot on a surface of the portable electronic device. For example, the hotspot detector 210 of FIG. 2 can detect the first hotspot 108A of FIG. 1 on the back surface 106. In some implementations, detecting the hotspot includes detecting voltage differences at a thermopile mesh coupled to a back cover of the portable electronic device. For example, the hotspot detector 210 of FIG. 2 (e.g., the controller 214, the integrated circuit 124, or both) can perform hotspot detection at various locations in the heat dissipation zone 134 based on differences in voltages detected at the peripheral ends of wires of the thermopile mesh 212. In some implementations, based on the detected voltages, the hotspot detector 210 determines relative or absolute skin temperatures associated with the locations of intersections of wires of the thermopile mesh 212 and compares the determined skin temperatures to a threshold (e.g., a skin temperature threshold) to detect hotspot locations.

The method 600 includes, at block 604, biasing electrodes at a set of liquid retention structures at the surface of the portable electronic device to transport liquid from a first location of the surface to a second location of the surface that corresponds to the hotspot. For example, the hotspot detector 210 (e.g., the controller 214, the integrated circuit 124, or both) can select one or more electrowetting paths to transport liquid (e.g., water) from the first location 180 (e.g., in the storage zone 136) of the back surface 106 to hotspot locations in the heat dissipation zone 134. In some implementations, the first location is within a storage zone and the second location is within a thermal dissipation zone. To illustrate, the hotspot detector 210 (e.g., the controller 214, the integrated circuit 124, or both) can select the electrowetting path 160 of FIG. 1 and generate control signals to apply a sequence of alternating voltage biases to the electrodes 262 at the liquid retention structures 150 along the electrowetting path 160 of FIG. 1 to transport the liquid from the first location 180 in the storage zone 136 to the first hotspot 108A at the second location 184 in the heat dissipation zone 134. The hotspot detector 210 (e.g., the controller 214, the integrated circuit 124, or both) can also select the electrowetting path 162 of FIG. 1 and generate control signals to apply a sequence of alternating voltage biases to the electrodes 262 at the liquid retention structures 150 along the electrowetting path 162 of FIG. 1 to transport liquid from the first location 180 in the storage zone 136 to the second hotspot 108B at the third location 188 in the heat dissipation zone 134.

In some implementations, the biasing of the electrodes causes electrowetting-on-dielectric transport of the liquid to the second location to be performed until a skin temperature at the second location is below a threshold. For example, the hotspot detector 210 of FIG. 2 (e.g., the controller 214, the integrated circuit 124, or both) can continuously, periodically, or occasionally repeat the temperature detection at the hotspot location and cease the transport of liquid to locations that have been sufficiently cooled and no longer qualify as a hotspot.

### Exemplary Electronic Devices

FIG. 7 illustrates various electronic devices that may include or be integrated with any of the device 100 or another device that includes a heat dissipation mechanism configured to perform evaporative cooling as disclosed herein. For example, a mobile phone device 702, a laptop computer device 704, a fixed location terminal device 706, a wearable device 708, or a vehicle 710 (e.g., an automobile or an aerial device) may include a device 700. The device 700 can include, for example, the device 100 of FIG. 1, the device 200 of FIG. 2, the device 300 of FIG. 3, the device 400 of FIG. 4, or another device that includes a heat dissipation mechanism configured to perform evaporative cooling as disclosed herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

In a particular implementation, the device 100, the portable electronic device 120, the device 200, or another device described herein, includes at least one processor and a memory that stores instructions that are executable by the at least one processor to implement functionality described with reference to the hotspot detector 210, the controller 214, or a combination thereof. In some implementations, a non-transitory computer-readable storage medium (e.g., a computer-readable storage device, such as a memory) includes instructions that, when executed by at least one processor, cause the at least one processor to detect a hotspot (e.g., the first hotspot 108A) on a surface (e.g., the back surface 106) of a portable electronic device (e.g., the portable electronic device 120); and bias electrodes (e.g., the electrodes 262) at a set of liquid retention structures (e.g., the liquid retention structures 150) at the surface of the portable electronic device to transport liquid (e.g., the liquid 280) from a first location (e.g., the first location 180) of the surface to a second location (e.g., the second location 184) of the surface that corresponds to the hotspot.

In conjunction with the described implementations, an apparatus includes means for providing an outer surface of a portable electronic device. For example, the means for providing the outer surface can correspond to the cover 102, one or more other structures configured to provide the outer surface of the portable electronic device, or any combination thereof.

The apparatus also includes means for dissipating heat to evaporatively cool the portable electronic device. For example, the means for dissipating heat can include the heat dissipation mechanism 140, one or more other structures or materials for dissipating heat, or any combination thereof. The means for dissipating heat includes: a set of means for retaining liquid located at the outer surface; and a set of means for transporting liquid at the means for retaining liquid from a first location of the outer surface to a second location of the outer surface. The means for retraining liquid can correspond to one or more of the liquid retention structures 150, the protrusions 250, the cap portions 256, the pillars 252, the hygroscopic coating 266, one or more other structures for retaining liquid located at the outer surface, or any combination thereof. The means for transporting liquid at the means for retaining liquid from a first location of the outer surface to a second location of the outer surface can correspond to one or more of the electrodes 262, the dielectric material 264, the protrusions 250, the hotspot detector 210, the controller 214, one or more other structures, materials, or electronic components configured to transport liquid at the means for retaining liquid from a first location of the outer surface to a second location of the outer surface, or any combination thereof.

One or more of the components, processes, features, and/or functions illustrated in FIGS. 1-7 may be rearranged and/or combined into a single component, process, feature or function or embodied in several components, processes, or functions. Additional elements, components, processes, and/or functions may also be added without departing from the disclosure. It should also be noted FIGS. 1-7 and its corresponding description in the present disclosure is not limited to dies and/or ICs. In some implementations, FIGS. 1-7 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a cover configured to provide an outer surface of a portable electronic device; and a heat dissipation mechanism integrated in the cover and configured to evaporatively cool the portable electronic device, wherein the heat dissipation mechanism includes: a set of liquid retention structures located at the outer surface; and a set of electrodes coupled to the set of liquid retention structures and configured to enable transport of liquid at the liquid retention structures from a first location of the outer surface to a second location of the outer surface.

Example 2 includes the device of Example 1, wherein the heat dissipation mechanism is configured to transport the liquid via electrowetting.

Example 3 includes the device of Example 1 or Example 2, wherein the heat dissipation mechanism is configured to transport the liquid from the first location having a first temperature to the second location having a second temperature that is higher than the first temperature.

Example 4 includes the device of any of Examples 1 to 3, wherein the set of liquid retention structures includes a plurality of protrusions extending outward from the outer surface, wherein a spacing between a first protrusion of the plurality of protrusions and a second protrusion of the plurality of protrusions that is adjacent to the first protrusion enables retention of water between the first protrusion and the second protrusion.

Example 5 includes the device of Example 4, wherein the first protrusion and the second protrusion are nanostructures.

Example 6 includes the device of Example 5 or Example 6, wherein the first protrusion includes: a first pillar having an upper end and a lower end, wherein the lower end of the first pillar is coupled to the outer surface; and a first cap portion having an upper surface and a lower surface, wherein the lower surface of the first cap portion is coupled to the upper end of the first pillar. The second protrusion includes: a second pillar having an upper end and a lower end, wherein the lower end of the second pillar is coupled to the outer surface; and a second cap portion having an upper surface and a lower surface, wherein the lower surface of the second cap portion is coupled to the upper end of the second pillar.

Example 7 includes the device of Example 6, wherein a first electrode of the set of electrodes is coupled to the lower surface of the first cap portion, and a second electrode of the set of electrodes is coupled to the lower surface of the second cap portion.

Example 8 includes the device of Example 7, wherein each of the first electrode and the second electrode is coated with a dielectric material.

Example 9 includes the device of any of Examples 4 to 8, wherein the set of liquid retention structures includes a hygroscopic coating on at least one of: a portion of the outer surface that is between the first protrusion and the second protrusion; a sidewall of the first protrusion; or a sidewall of the second protrusion.

Example 10 includes the device of any of Examples 1 to 9 and further includes a hotspot detector coupled to the cover and configured to detect locations of hotspots at the outer surface, and wherein the heat dissipation mechanism is configured to transport liquid to the detected locations of the hotspots.

Example 11 includes the device of Example 10, wherein the hotspot detector includes a thermopile mesh.

Example 12 includes the device of any of Examples 1 to 11, wherein a first portion of the set of liquid retention structures are included in a thermal dissipation zone and a second portion of the set of liquid retention structures are included in a storage zone.

Example 13 includes the device of Example 12, wherein a third portion of the set of liquid retention structures are included in a collection zone.

According to Example 14, a portable electronic device includes a display panel at a front surface of the portable electronic device; an integrated circuit coupled to the display panel; a cover coupled to the integrated circuit at a back surface of the portable electronic device; and a heat dissipation mechanism integrated in the cover and configured to evaporatively cool the portable electronic device. The heat dissipation mechanism includes a set of liquid retention structures located at the back surface, and a set of electrodes coupled to the set of liquid retention structures and configured to enable transport of liquid at the liquid retention structures from a first location of the back surface to a second location of the back surface.

Example 15 includes the portable electronic device of Example 14, wherein the heat dissipation mechanism is configured to transport the liquid via electrowetting.

Example 16 includes the portable electronic device of Example 14 or Example 15, wherein the heat dissipation mechanism is configured to transport the liquid from the first location having a first temperature to the second location having a second temperature, wherein the second temperature is higher than the first temperature due to heat generation of the integrated circuit.

Example 17 includes the portable electronic device of any of Examples 14 to 16, wherein the set of liquid retention structures includes nanostructures.

Example 18 includes the portable electronic device of any of Examples 14 to 17, wherein the set of liquid retention structures includes a plurality of protrusions extending outward from the back surface, wherein a spacing between a first protrusion of the plurality of protrusions and a second protrusion of the plurality of protrusions that is adjacent to the first protrusion enables retention of water between the first protrusion and the second protrusion.

Example 19 includes the portable electronic device of Example 18, wherein the first protrusion and the second protrusion are nanostructures.

Example 20 includes the portable electronic device of Example 18 or Example 19, wherein the first protrusion includes: a first pillar having an upper end and a lower end, wherein the lower end of the first pillar is coupled to the back surface; and a first cap portion having an upper surface and a lower surface, wherein the lower surface of the first cap portion is coupled to the upper end of the first pillar. The second protrusion includes: a second pillar having an upper end and a lower end, wherein the lower end of the second pillar is coupled to the back surface; and a second cap portion having an upper surface and a lower surface, wherein the lower surface of the second cap portion is coupled to the upper end of the second pillar.

Example 21 includes the portable electronic device of Example 20, wherein a first electrode of the set of electrodes is coupled to the lower surface of the first cap portion, and a second electrode of the set of electrodes is coupled to the lower surface of the second cap portion.

Example 22 includes the portable electronic device of Example 21, wherein each of the first electrode and the second electrode is coated with a dielectric material.

Example 23 includes the portable electronic device of any of Examples 18 to 22, wherein the set of liquid retention structures includes a hygroscopic coating on at least one of a portion of the back surface that is between the first protrusion and the second protrusion, a sidewall of the first protrusion, or a sidewall of the second protrusion.

Example 24 includes the portable electronic device of any of Examples 14 to 23 and further includes a hotspot detector coupled to the cover and configured to detect locations of hotspots at the back surface, and wherein the heat dissipation mechanism is configured to transport liquid to the detected locations of the hotspots.

Example 25 includes the portable electronic device of Example 24, wherein the hotspot detector includes a thermopile mesh.

Example 26 includes the portable electronic device of any of Examples 14 to 25, wherein a first portion of the set of liquid retention structures are included in a thermal dissipation zone and a second portion of the set of liquid retention structures are included in a storage zone.

Example 27 includes the portable electronic device of Example 26, wherein a third portion of the set of liquid retention structures are included in a collection zone.

According to Example 28, a method of cooling a portable electronic device includes detecting a hotspot on a surface of the portable electronic device; and biasing electrodes at a set of liquid retention structures at the surface of the portable electronic device to transport liquid from a first location of the surface to a second location of the surface that corresponds to the hotspot.

Example 29 includes the method of Example 28, wherein the first location is within a storage zone and the second location is within a thermal dissipation zone.

Example 30 includes the method of Example 28 or Example 29, wherein detecting the hotspot includes detecting voltage differences at a thermopile mesh coupled to a back cover of the portable electronic device, and wherein the biasing of the electrodes causes electrowetting-on-dielectric transport of the liquid to the second location to be performed until a skin temperature at the second location is below a threshold.

According to Example 31, a non-transitory computer-readable medium stores instructions that, when executed by one or more processors, cause the one or more processors to detect a hotspot on a surface of a portable electronic device; and bias electrodes at a set of liquid retention structures at the surface of the portable electronic device to transport liquid from a first location of the surface to a second location of the surface that corresponds to the hotspot.

According to Example 32, a device includes means for providing an outer surface of a portable electronic device; and means for dissipating heat to evaporatively cool the portable electronic device, wherein the means for dissipating heat includes: a set of means for retaining liquid located at the outer surface; and a set of means for transporting liquid at the means for retaining liquid from a first location of the outer surface to a second location of the outer surface.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a cover configured to provide an outer surface of a portable electronic device; and
a heat dissipation mechanism integrated in the cover and configured to evaporatively cool the portable electronic device, wherein the heat dissipation mechanism includes:
a set of liquid retention structures located at the outer surface; and
a set of electrodes coupled to the set of liquid retention structures and configured to enable transport of liquid at the liquid retention structures from a first location of the outer surface to a second location of the outer surface.

2. The device of claim 1, wherein the heat dissipation mechanism is configured to transport the liquid via electrowetting.

3. The device of claim 1, wherein the heat dissipation mechanism is configured to transport the liquid from the first location having a first temperature to the second location having a second temperature that is higher than the first temperature.

4. The device of claim 1, wherein the set of liquid retention structures includes a plurality of protrusions extending outward from the outer surface, wherein a spacing between a first protrusion of the plurality of protrusions and a second protrusion of the plurality of protrusions that is adjacent to the first protrusion enables retention of water between the first protrusion and the second protrusion.

5. The device of claim 4, wherein the first protrusion and the second protrusion are nanostructures.

6. The device of claim 4, wherein:
the first protrusion includes:
a first pillar having an upper end and a lower end, wherein the lower end of the first pillar is coupled to the outer surface; and
a first cap portion having an upper surface and a lower surface, wherein the lower surface of the first cap portion is coupled to the upper end of the first pillar, and
the second protrusion includes:
a second pillar having an upper end and a lower end, wherein the lower end of the second pillar is coupled to the outer surface; and
a second cap portion having an upper surface and a lower surface, wherein the lower surface of the second cap portion is coupled to the upper end of the second pillar.

7. The device of claim 6, wherein:
a first electrode of the set of electrodes is coupled to the lower surface of the first cap portion; and
a second electrode of the set of electrodes is coupled to the lower surface of the second cap portion.

8. The device of claim 7, wherein each of the first electrode and the second electrode is coated with a dielectric material.

9. The device of claim 4, wherein the set of liquid retention structures includes a hygroscopic coating on at least one of:
a portion of the outer surface that is between the first protrusion and the second protrusion;
a sidewall of the first protrusion; or
a sidewall of the second protrusion.

10. The device of claim 1, further comprising a hotspot detector coupled to the cover and configured to detect locations of hotspots at the outer surface, and wherein the heat dissipation mechanism is configured to transport liquid to the detected locations of the hotspots.

11. The device of claim 10, wherein the hotspot detector includes a thermopile mesh.

12. The device of claim 1, wherein a first portion of the set of liquid retention structures are included in a thermal dissipation zone and a second portion of the set of liquid retention structures are included in a storage zone.

13. The device of claim 12, wherein a third portion of the set of liquid retention structures are included in a collection zone.

14. A portable electronic device comprising:
a display panel at a front surface of the portable electronic device;
an integrated circuit coupled to the display panel;
a cover coupled to the integrated circuit at a back surface of the portable electronic device; and
a heat dissipation mechanism integrated in the cover and configured to evaporatively cool the portable electronic device, wherein the heat dissipation mechanism includes:
a set of liquid retention structures located at the back surface; and
a set of electrodes coupled to the set of liquid retention structures and configured to enable transport of liquid at the liquid retention structures from a first location of the back surface to a second location of the back surface.

15. The portable electronic device of claim 14, wherein the heat dissipation mechanism is configured to transport the liquid via electrowetting.

16. The portable electronic device of claim 14, wherein the heat dissipation mechanism is configured to transport the liquid from the first location having a first temperature to the second location having a second temperature, wherein the second temperature is higher than the first temperature due to heat generation of the integrated circuit.

17. The portable electronic device of claim 14, wherein the set of liquid retention structures includes nanostructures.

18. A method of cooling a portable electronic device, comprising:
detecting a hotspot on a surface of the portable electronic device; and
biasing electrodes at a set of liquid retention structures at the surface of the portable electronic device to transport liquid from a first location of the surface to a second location of the surface that corresponds to the hotspot.

19. The method of claim 18, wherein the first location is within a storage zone and the second location is within a thermal dissipation zone.

20. The method of claim 19, wherein detecting the hotspot includes detecting voltage differences at a thermopile mesh coupled to a back cover of the portable electronic device, and wherein the biasing of the electrodes causes electrowetting-on-dielectric transport of the liquid to the second location to be performed until a skin temperature at the second location is below a threshold.
